(19) United States
(12) Patent Application Publication
(10) Pub. No.: US 2019/0067899 A1
(43) Pub. Date: Feb. 28, 2019

(54) METHOD FOR FABRICATING SEMICONDUCTOR OPTICAL DEVICE

(71) Applicant: SUMITOMO ELECTRIC INDUSTRIES, LTD., Osaka (JP)

(72) Inventor: Yukihiro TSUJI, Osaka (JP)

(73) Assignee: SUMITOMO ELECTRIC INDUSTRIES, LTD., Osaka (JP)

(21) Appl. No.: 16/107,882

(22) Filed: Aug. 21, 2018

(30) Foreign Application Priority Data
Aug. 23, 2017 (JP) 2017-160145

(51) Int. Cl. H01S 5/02; H01S 5/183

(52) U.S. Cl. CPC H01S 5/0216; H01S 5/0213; H01S 5/183

(57) ABSTRACT

A method for fabricating a semiconductor optical device includes: preparing a product having a supporting base with a top face and a back face, a semiconductor product mounted on the top face, and an adhesive film with a film containing pressure sensitive material, the adhesive film being between the semiconductor product and the supporting base in the product, and the semiconductor product including a semiconductor laminate and a patterned resist layer on the semiconductor laminate; applying force to the product to produce an intermediate product from the product, the adhesive film bonding the semiconductor product and the top face of the supporting base to each other; disposing the intermediate product on a stage of an etching apparatus; and etching the semiconductor product in the intermediate product with the patterned resist layer in the etching apparatus while the semiconductor product being cooled through the stage.

### BACKGROUND OF THE INVENTION

### Field of the Invention

The present invention relates to a method for fabricating a semiconductor optical device. This application claims the benefit of priority from Japanese Patent Application No. 2017-160145 filed on Aug. 23, 2017, which is herein incorporated by reference in its entirety.

### Related Background Art

Japanese Unexamined Patent Application Publication No. 2012-43928, referred to as Patent Document 1, discloses a plasma processing method and a plasma processing apparatus. Japanese Unexamined Patent Application Publication No. 2007-201404, referred to as Patent Document 2, discloses a plasma processing method and a plasma processing apparatus.

### SUMMARY OF THE INVENTION

A method for fabricating a semiconductor optical device according to one aspect of the present invention: preparing a product having a supporting base with a top face and a back face, a semiconductor product mounted on the top face, and an adhesive film including a pressure sensitive material, the adhesive film being between the semiconductor product and the supporting base in the product, and the semiconductor product including a semiconductor laminate and a patterned resist layer on the semiconductor laminate; applying force to the product to produce an intermediate product from the product, the adhesive film bonding the semiconductor product and the top face of the supporting base to each other; disposing the intermediate product on a stage of an etching apparatus; and etching the semiconductor product in the intermediate product with the patterned resist layer in the etching apparatus while the semiconductor product being cooled through the stage.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a cross-sectional view showing a semiconductor laser which is made by a method for fabricating a semiconductor optical device according to an embodiment.

FIG. 2A is a cross-sectional view showing a major step in a method for fabricating a semiconductor laser according to the embodiment.

FIG. 2B is a cross-sectional view showing a major step in the method according to the embodiment.

FIG. 3A is a cross-sectional view showing a major step in the method according to an embodiment.

FIG. 3B is a cross-sectional view showing a major step in the method according to an embodiment.

FIG. 3C is a cross-sectional view showing a major step in the method according to an embodiment.

FIG. 4A is a cross-sectional view showing a major step in the method according to an embodiment.

FIG. 4B is a cross-sectional view showing a major step in the method according to an embodiment.

FIG. 5 is a schematic view showing a major step, which forms an intermediate product with an apparatus which can bond a semiconductor product to a supporting member with an adhesive film.

FIG. 6 is a schematic cross-sectional view showing a structure of a double-sided adhesive film.

FIG. 7 is a flowchart showing a method for producing an intermediate product from a laminate product.

FIG. 8A is a schematic diagram showing the back face of the pressure sensitive film in change in color, indicated by hatching.

FIG. 8B is a schematic diagram showing the back face of the pressure sensitive film in change in color, indicated by hatching.

FIG. 8C is a schematic diagram showing the back face of the pressure sensitive film in change in color, indicated by hatching.

FIG. 9A is a schematic diagram showing the back face of the pressure sensitive film in change in color, indicated by hatching.

FIG. 9B is a schematic diagram showing the back face of the pressure sensitive film in change in color, indicated by hatching.

FIG. 9C is a schematic diagram showing the back face of the pressure sensitive film in change in color, indicated by hatching.

FIG. 10 is a graph showing the relationship between the pressing time and the ratio of the area of the discolored region to the total area inside the O-ring.

FIG. 11A is a schematic view showing a major step for forming a mask on the laminate product in the method according to the embodiment.

FIG. 11B is a schematic view showing a major step for etching the laminate product with the mask in the method according to the embodiment.

FIG. 12A is a schematic view showing a major step for removing the film from the etched product in the method according to the embodiment.

FIG. 12B is a schematic view showing a major step for removing the mask in the method according to the embodiment.

FIG. 13A is a schematic diagram showing the back face of the pressure sensitive film in change in color, indicated by hatching, in the bonding step in a modified example.

FIG. 13B is a schematic diagram showing the back face of the pressure sensitive film in change in color, indicated by hatching, in the bonding step in a modified example.

FIG. 13C is a schematic diagram showing the back face of the pressure sensitive film in change in color, indicated by hatching, in the bonding step in a modified example.

FIG. 14A is a schematic diagram showing the back face of the pressure sensitive film in change in color, indicated by hatching, in the bonding step in a modified example.

FIG. 14B is a schematic diagram showing the back face of the pressure sensitive film in change in color, indicated by hatching, in the bonding step in a modified example.

FIG. 14C is a schematic diagram showing the back face of the pressure sensitive film in change in color, indicated by hatching, in the bonding step in a modified example.

FIG. 15 is a schematic view showing a pasting apparatus according to an embodiment.

FIG. 16A us a schematic view showing a warpage of a wafer.

FIG. 16B is a schematic view showing rough faces of the double-sided adhesive film.

FIG. 16C is a schematic view showing roughness of the top face of the tray.

### DESCRIPTION OF THE EMBODIMENTS

A substrate is bonded to a tray with a heat-peelable adhesive film which has a base sheet and two adhesive layers on respective sides of the base sheet. The substrate and the tray thus bonded to each other are loaded to a plasma-processing apparatus to dispose them on the table thereof. The plasma-processing apparatus processes the surface of the substrate on the tray with plasma. This plasma treatment is followed by separating the substrate away from the tray by heating the tray.

Specifically, fabricating a semiconductor optical device includes growing a semiconductor laminate on a wafer to form the substrate, and processing the semiconductor laminate with a mask by plasma etching, such as reactive ion etching. The reactive ion etching uses ion species in the plasma that collide with the surface of the semiconductor laminate in the reaction chamber. The collision of the ion species enables both sputtering and chemical reaction of the semiconductor laminate, resulting in etching the semiconductor laminate.

The plasma etching also heats the semiconductor laminate to raise the temperature thereof. A too high temperature may deteriorate resist of the mask. In order to dissipate the heat through the tray, the plasma-processing apparatus cools the tray during the plasma etching.

Some of the semiconductor laminates on the wafers, which are thus etched while the tray is cooled, are defective because of deterioration of their resist masks. The inventor's teachings reveal that the deterioration of resist may be caused by temperature rise of the semiconductor laminate. What is needed is to reduce the temperature rise of the resist mask during the plasma etching. The insufficient cooling of the wafer may be associated with loose contact between the heat-peelable adhesive film and the tray and wafer. The loose contact therebetween prevents the wafer from being sufficiently cooled through the tray, so that the poor heat dissipation raises the temperature of the wafer, resulting in deteriorating the resist of the mask. The mask of deteriorated resist cannot overcome the bombardment of ions and particles in the plasma, and makes the etched product defective, leading to reduction in production yield.

In etching the semiconductor laminate on the wafer that is attached to the tray through the heat-peelable adhesive film, the wafer may be peeled off from the tray during the plasma etching. The inventor's findings reveal that there are voids at the interfaces between the heat-peelable adhesive film and the tray and wafer, so that the wafer that is peeled from the tray is not firmly attached to the tray with the heat-peelable adhesive film. These voids may reduce the heat transfer. What is needed is to bring the wafer into close contact with the tray for plasma etching.

It is an object of one aspect of the present invention to provide a method for fabricating a semiconductor optical device that can allows a close contact between the tray for plasma etching and a product to be etched.

A description will be given of embodiments according to the above aspect.

A method for fabricating a semiconductor optical device according to an embodiment: (a) preparing a product having a supporting base with a top face and a back face, a semiconductor product mounted on the top face, and an adhesive film including a pressure sensitive material, the adhesive film being between the semiconductor product and the supporting base in the product, and the semiconductor product including a semiconductor laminate and a patterned resist layer on the semiconductor laminate; (b) applying force to the product to produce an intermediate product from the product, the adhesive film bonding the semiconductor product and the top face of the supporting base to each other; (c) disposing the intermediate product on a stage of an etching apparatus; and (d) etching the semiconductor product in the intermediate product with the patterned resist layer in the etching apparatus while the semiconductor product being cooled through the stage.

The fabricating method uses a film containing pressure sensitive material disposed between the tray and the wafer. The pressure sensitive film changes its color in response to a pressure applied thereto. Applying a pressing force between the wafer and the tray causes non-uniform discoloration of the pressure sensitive film over the surface of the wafer. The variation in discoloration of the pressure sensitive film shows a variation in contact between the tray and the wafer. The discoloration can be observed through the back side of the tray, and this observation can determine that the pressing force has changed the pressure sensitive film in color to a desired level, whereby the pressing step brings the intermediate product to completion. The intermediate product allows the heat, applied to the epitaxial wafer during plasma etching, to dissipate through the tray.

In the determining step of the above fabricating method, the ratio of the discolored area, which indicates change in color in the pressure sensitive film, to the predetermined area of the pressure sensitive film reaches or exceeds the predetermined ratio. This makes it possible to judge whether the wafer uniformly adheres to the tray over the wafer. Specifically, imaging the back face of the pressure sensitive film through the other side of the tray allows the observation of the discolored area of the pressure sensitive film, and this observation with the images allows the judgment of the completion of the intermediate product in view of uniformity in the discoloration with a computer.

In the preparation step of the fabricating method, the wafer may adhere to the pressure sensitive film with a double-sided adhesive film having a heat-peelable adhesive on the face to which the wafer adheres. This heat-peelable adhesive easily can separate the tray and the pressure sensitive film from the wafer after the plasma etching.

In the preparation step of the above fabricating method, the pressure sensitive film may adhere to the tray with another double-sided adhesive film having a heat peelable adhesive on the face to which the tray adheres. This heat-peelable adhesive ensures the separation of the tray and the pressure sensitive film from the wafer after the plasma etching.

In the above fabricating method, the semiconductor optical device may include a vertical cavity surface emitting laser (abbreviated as VCSEL). Fabricating the VCSEL excludes using both wet etching with hydrofluoric acid and dry etching with a fluorocarbon gas, so that a silicon oxide film or a silicon nitride film cannot be used as an etching mask. The etching mask in fabrication of the VCSEL includes resist. Using the resist mask in the fabricating method is particularly effective in fabricating the VCSEL.

In the method according to and embodiment, the stage of the etching apparatus is coupled to a cooler, and the stage is in contact with the back face of the supporting member.

In the method according to and embodiment, etching apparatus processes the semiconductor product by plasma-etching.

In the method according to and embodiment, the adhesive film has a heat-peelable adhesive sheet between the semiconductor product and the top face of the supporting base.

In the method according to and embodiment, the adhesive film has a heat-peelable adhesive sheet between the supporting base and the semiconductor product.

In the method according to and embodiment, the adhesive film has a first heat-peelable adhesive sheet between the adhesive film and the top face of the supporting base, and a second heat-peelable adhesive sheet between the adhesive film and the semiconductor product.

In the method according to and embodiment, the semiconductor product includes semiconductor layers for an upper distributed Bragg reflector, an active layer and a lower distributed Bragg reflector.

In the method according to and embodiment, the semiconductor optical device includes a vertical cavity surface emitting laser, and the patterned resist layer defines a mesa shape for the vertical cavity surface emitting laser.

In the method according to and embodiment, the supporting base is made of quartz glass.

In the method according to and embodiment, applying force to the product includes disposing an O-ring on the patterned resist layer, disposing a lid on the O-ring and the patterned resist layer to form a hermetically sealed cavity, and depressurizing the hermetically sealed cavity to apply the force to the intermediate product while illuminating the back face with rays of light.

The teachings of the present invention can be readily understood by considering the following detailed description with reference to the accompanying drawings shown as examples.

Referring to the accompanying drawings, embodiments according to a method for fabricating a semiconductor optical device will be illustrated below. When possible, the same portions will be denoted by the same reference numerals.

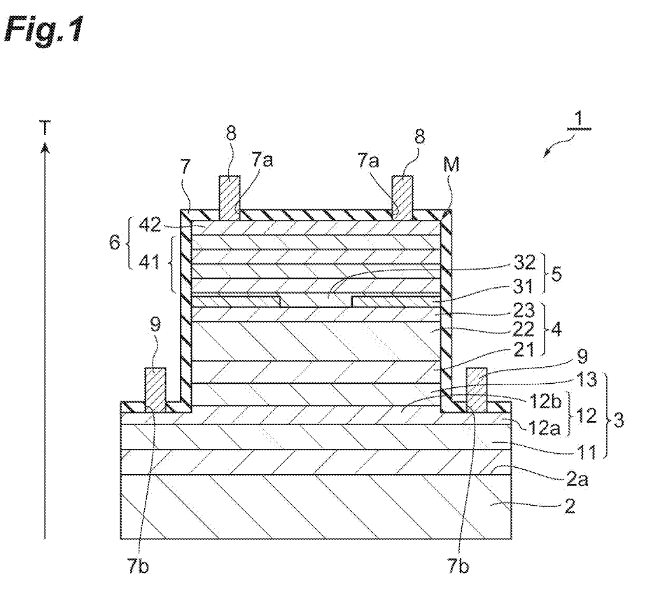

FIG. 1 is a cross-sectional view showing a semiconductor optical device, for example a semiconductor laser 1, fabricated by a method for fabricating a semiconductor optical device according to the present embodiment. Referring to FIG. 1, the semiconductor laser 1 can be a vertical cavity surface emitting laser (abbreviated as VCSEL). The semiconductor laser 1 includes a semiconductor base 2, a first laminate 3, an active layer 4, a current constricting layer 5, a second laminate 6, an insulating film 7, and electrodes 8 and 9. The first laminate 3, the active layer 4, the current constricting layer 5, and the second laminate 6 are stacked in order on the semiconductor base 2. The semiconductor laser 1 has a semiconductor mesa M, which includes a part of the first laminate 3, the active layer 4, the current constricting layer 5, and the second laminate 6, which are arranged along the direction of an axis T (hereinafter referred to as “the direction T”).

The semiconductor base 2 can be a group III-V semiconductor substrate, for example, an i- or n-type GaAs substrate. The semiconductor base 2 includes an n-type semiconductor, which is doped with n-type dopant, such as Te (tellurium) and Si (silicon). Group III-V semiconductor includes one or more group III elements, such as Al (aluminum), Ga (gallium) and In (indium), and one or more group V elements, such as As (arsenic) and Sb (antimony).

The semiconductor base 2 has a thickness of, for example, 100 to 200 micrometers, which results from a semiconductor wafer product, which has been thinned, for example by polishing, in the method for fabricating the semiconductor laser 1, for the semiconductor base 2. The semiconductor laser 1 thus thinned is mounted on the circuit board.

The first laminate 3 serves as a lower distributed Bragg reflector (a lower DBR), which is under the active layer 4, and includes multiple semiconductor layers. The first laminate 3 is disposed on the front face 2a of the semiconductor base 2, and has, for example, a first superlattice structure 11, a contact layer 12, and a second superlattice structure 13. The first superlattice 11, the contact layer 12, and the second superlattice 13 are sequentially arranged on the face 2a of the semiconductor base 2 in the direction T such that the contact layer 12 is disposed between the first and second superlattice structures 11 and 13.

The first superlattice structure 11 is made of i-type semiconductor. The first superlattice 11 has an arrangement of unit structures each including multiple semiconductor layers different from each other. Each structure unit structures includes, for example, an AlGaAs layer (having an Al composition of 0.12) and an AlGaAs layer (having an Al composition of 0.90). The first superlattice 11 has a stacking number of the unit structures in the range of, for example, 50 to 100. The first superlattice 11 has a thickness of, for example, 4000 to 6000 nm.

The contact layer 12 made of n-type semiconductor, which is in contact with the electrode 9 of the semiconductor laser 1, forming a single layer. The contact layer 12 is made of, for example, a GaAs doped with Si. The contact layer 12 has a first portion 12a and a second portion 12b, which can be different in thickness from each other. The first and second portions 12a and 12b are arranged along the front face of the semiconductor base 2. The first portion 12a is outside the semiconductor mesa M to make contact with the electrode 9. The second portion 12b has one part and another part contained by the semiconductor mesa M. The first portion 12a has a thickness equal to or less than that of the second portion 12b, for example, 250 to 500 nm in view of contact resistance. The second portion 12b has a thickness of not less than that of the first portion 12a, for example not more than 500 nm.

The second superlattice 13 is made of n-type semiconductor doped with, for example Si, and is disposed on the second portion 12b of the contact layer 12. The second superlattice 13, which is similar to the first superlattice 11, has an arrangement of unit structures including multiple semiconductor layers different from each other. Each unit structure includes, for example, an AlGaAs layer (having an Al composition of 0.12) and an AlGaAs layer (having an Al composition of 0.90). The second superlattice 13 has a stacking number of unit structures in the range of, for example, 10 to 30. The second superlattice structure 13 has a thickness of, for example, 1000 to 2000 nm.

The active layer 4 is disposed on the second superlattice 13 of the first laminate 3 and can generate light through recombination of electrons and holes and. The active layer 4 has a lower spacer layer 21, a multiple quantum well structure 22, and an upper spacer layer 23, which are sequentially stacked on the first laminate 3 in the direction T. The multiple quantum well structure 22 is disposed between the lower and upper spacer layers 21 and 23. The active layer 4 has a thickness of, for example, 50 to 300 nm.

The lower spacer layer 21 is disposed between the second superlattice 13 and the multiple quantum well structure 22, and is made of semiconductor doped with an n-type dopant, such as a Si-doped AlGaAs layer (having an Al composition of 0.30). The multiple quantum well structure portion 22 includes, for example, GaAs layers each of which serves as a well layer, and AlGaAs layers each of which serves as a barrier layer. The GaAs layers and the AlGaAs layers are alternately arranged in the direction T. The upper spacer layer 23 includes an undoped semiconductor layer and a semiconductor layer doped with a p-type dopant. The undoped semiconductor layer is made, for example, an AlGaAs layer (having an Al composition of 0.30). The semiconductor layer is doped with a p-type dopant, such as zinc (Zn), and is especially Zn-doped AlGaAs (having an Al composition of 0.90). The p-type dopant encompasses Be (beryllium), Mg (magnesium), C (carbon), or Zn (zinc).

The current constricting layer 5 is disposed in the semiconductor mesa M to restrict current (carriers) into the active layer 4. The current constricting layer 5 has a high-resistance portion 31 and a low-resistance portion 32. The high resistance portion 31 encircles the low-resistance portion 32 on an axis extending in the direction T. The high-resistance portion 31 is made of group III oxide, the low-resistance portion 32 is formed of III-V compound semiconductor, for example, an AlGaAs layer of a high Al composition (for example, an Al composition of 0.98). The III-V compound semiconductor is provided with a high Al composition that allows an oxidant atmosphere to oxidize the III-V compound semiconductor. The low resistance portion 32 has an electrical resistance lower than that of the high resistance portion 31, and excludes aluminum oxide. The current constricting layer 5 has a thickness of, for example, 10 to 50 nm. The current constricting layer 5 allows current to flow through the low resistance portion 32, thereby narrowing the current path.

The second laminate 6 serves as an upper distributed Bragg reflector (an upper DBR) to the active layer 4, and includes multiple semiconductor layers. The second laminate 6 incorporates the current constricting layer 5, and alternatively is disposed on the current constricting layer 5. The second laminate 6 has, for example, a superlattice 41 and a contact layer 42. The superlattice 41 and the contact layer 42 are stacked in order along the direction T on the active layer. If needed, the superlattice 41 has a first part and a second part and the current constricting layer 5 is between the first part and the second part. The first and second parts of the superlattice 41 are arranged to form the upper DBR.

The superlattice 41 has a p-type conductivity. The superlattice 41 has an arrangement of units, which are similar to the first superlattice 11. Each unit structure includes, for example, an AlGaAs layer (having an Al composition of 0.12) and an AlGaAs layer (having an Al composition of 0.90). The superlattice 41 has a stacking number of unit structures in the range of, for example, 50 to 100. The superlattice 41 has a thickness of, for example, 3000 to 5000 nm. The superlattice 41 is doped with, for example, Zn. The contact layer 42 has a single semiconductor film that is in contact with the electrode 8. The contact layer 42 is made of, for example, Zn-doped GaAs. The contact layer 42 has a thickness of, for example, 100 to 300 nm.

The insulating film 7 serves as a protective film, which covers semiconductor layers in the semiconductor laser 1, and is made of, for example, inorganic insulating material. The inorganic insulating film includes a silicon-based inorganic film, such as a silicon oxide film, a silicon nitride film, and a silicon oxynitride film. The insulating film 7 has an opening portion 7a on the semiconductor mesa M and an opening portion 7b on an area apart from the semiconductor mesa M. The openings 7a and 7b penetrate through the insulating film 7 in the direction T, such that the opening 7a reaches the contact layer 42 and the opening 7b reaches the first portion 12a of the contact layer 12. The insulating film 7 may have a thickness of 200 to 500 nm, which can provide the semiconductor laser 1 with a high reflectance.

The electrode 8 is disposed on the semiconductor mesa M and has a part embedding in the opening portion 7a. The electrode 8 is in contact with the contact layer 42 via the opening 7a. The electrode 8 may have a laminate structure including, for example, a titanium layer, a platinum layer, and a gold layer.

The electrode 9 is disposed apart from the semiconductor mesa M and is embedded in the opening 7b. The electrode 9 is in contact with the first portion 12a of the contact layer 12 via the opening 7b. The electrode 9 may include, for example, a gold-germanium-nickel alloy layer.

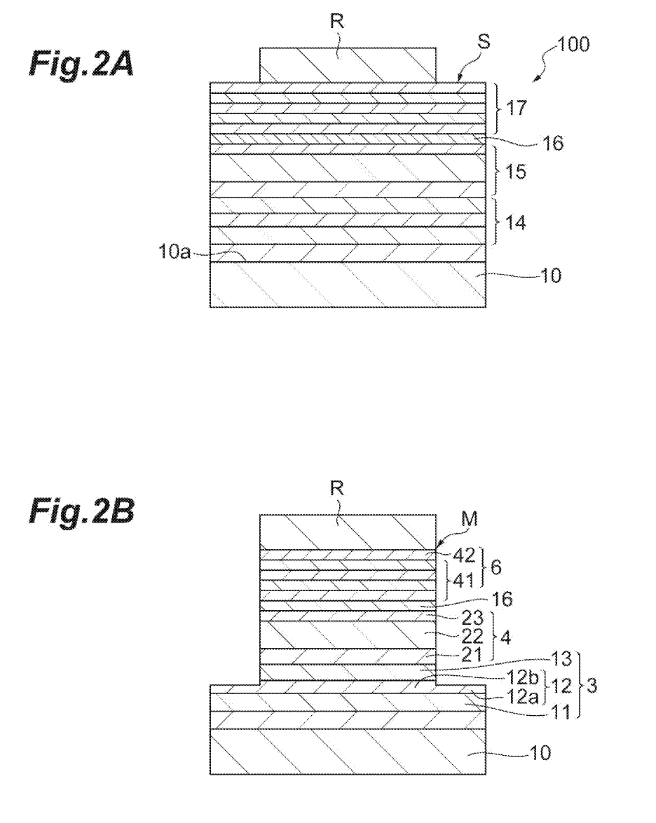

With reference to FIGS. 2A and 2B, FIGS. 3A, 3B and 3C, and FIGS. 4A and 4B, a description will be given of a method of fabricating the semiconductor laser 1 according to the embodiment below. FIGS. 2A to 4B each are a cross-sectional view illustrating a major step in a method for fabricating the semiconductor laser 1 according to the present embodiment.

The fabricating method begins with preparation of an epitaxial wafer 100 as shown in FIG. 2A. The epitaxial wafer 100 has a wafer 10 and a semiconductor laminate S for a VCSEL on the principal surface 10a of the wafer 10, which will later change into the semiconductor base 2. In this process, the second semiconductor laminate S is epitaxially grown on the principal surface 10a of the wafer 10, and includes the semiconductor layer 14 for the first laminate 3, the semiconductor layer 15 for the active layer 4, the semiconductor layer 16 for the current constricting layer 5, and the semiconductor layer 17 for the laminate 6. The semiconductor layers 14 to 17 are sequentially grown by molecular beam epitaxy or metal organic vapor phase epitaxy. In the next step, a resist mask R is formed by photolithography on the semiconductor laminate S of the epitaxial wafer to produce a semiconductor product from the epitaxial wafer. The resist mask R has a pattern. which defines the planar shape of the semiconductor mesa M as shown in FIG. 1, covering a part of the surface on the semiconductor laminate S, and an opening defined by the pattern.

The epitaxial wafer 100 (the surface on the semiconductor laminate S) is etched with the resist mask R by plasma etching (for example, reactive ion etching). As shown in FIG. 2B, the etching with the resist mask R removes a part of the semiconductor laminate S to form the semiconductor layers 14 to 17. The etching process forms the semiconductor mesa M, which includes the second portion 12b of the second semiconductor layer 12, and exposes the first portion 12a of the remaining contact layer 12. The details of this process will be described low. After this etching, the resist mask R is removed using, for example oxygen plasma or an organic solvent.

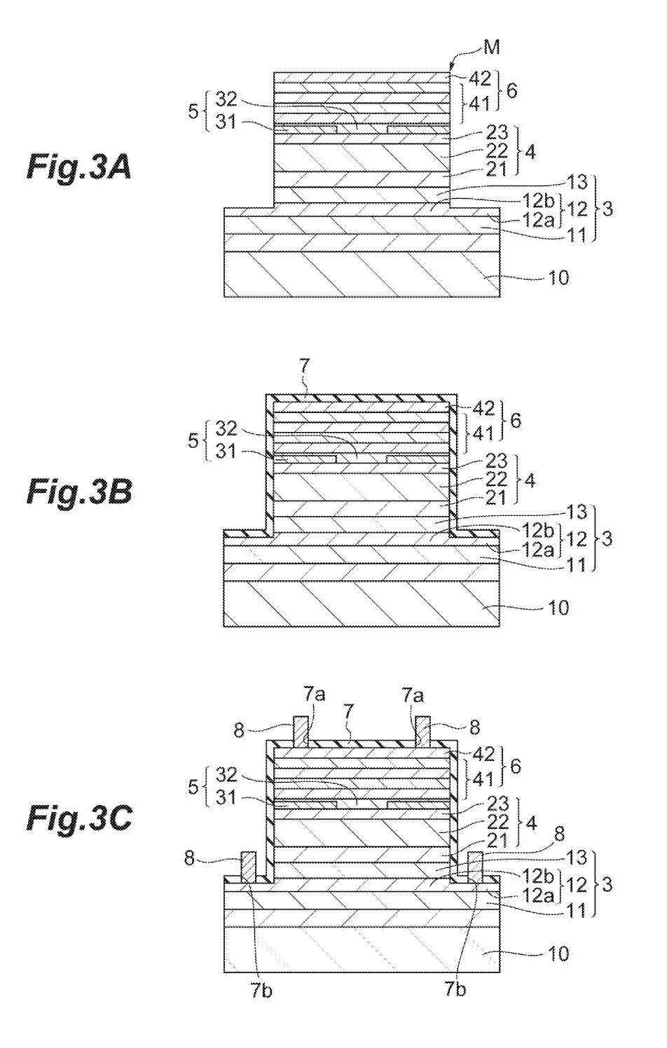

As shown in FIG. 3A, the semiconductor layer 16 is partly oxidized to form the current constricting layer 5 in a processing apparatus. Specifically, the semiconductor mesa M is exposed to a high-temperature steam in the processing apparatus, so that the oxidation of the semiconductor layer 16, which has the highest Al composition, proceeds from the side face of the mesa M to change the outer portion of the semiconductor layer 16 into oxide. The current constricting layer 5 is provided with the high resistance portion 31 in the outer portion of the mesa and the low resistance portion 32 in the inner portion of the mesa, which is encircled by the high resistance portion 31.

As shown in FIG. 3B, an insulating film 7 is formed so as to cover the mesa M. The insulating film 7 is formed by, for example, plasma enhanced CVD. The insulating film 7 is formed by, for example, dry etching to form an opening 7a on the contact layer 42 and an opening 7b on the first portion 12a of the contact layer 12 at the same time.

As shown in FIG. 3C, after forming the openings 7a and 7b, the electrode 8 is formed in contact with the contact layer 42, and the electrode 9 is formed in the opening 7b in contact with the first portion 12a of the contact layer 12. In the embodiment, the formation of the electrode 9 in the opening 7a follows the formation of the electrode 8.

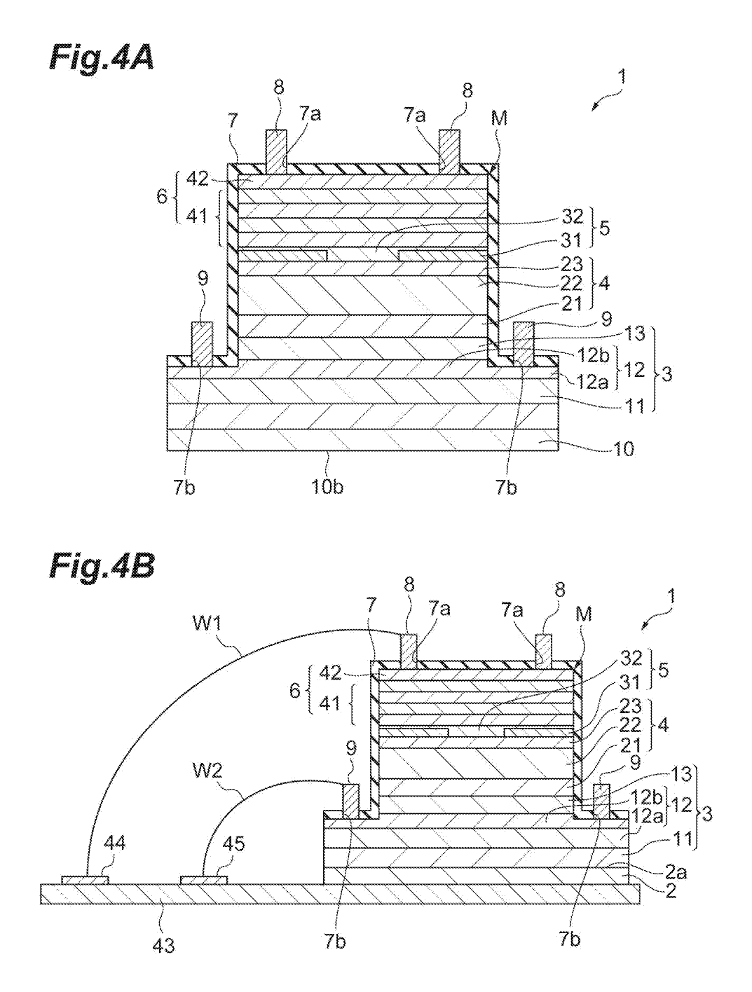

As shown in FIG. 4A, after forming the electrodes 8 and 9, the wafer 10 is thinned. Specifically, the back face 10b of the wafer 10 is polished using, for example, a back grinder or a lapping machine. The wafer 10 thus thinned is separated using, for example, a dicer to form chip-shaped semiconductor lasers 1.

As shown in FIG. 4B, the semiconductor laser 1 is mounted on the circuit board 43. Specifically, the semiconductor laser 1 is die-bonded to the circuit board 43 using an adhesive. Then, the electrode 8 is electrically connected to the electrode 44, located on the circuit board 43, by a bonding conductor W1. The electrode 9 is electrically connected to the electrode 45, located on the circuit board 43, by the bonding conductor W2.

A description will be given of the etching step (shown in FIG.

2B) in detail. The above-described etching process applies plasma radiation in the etching (for example, reactive ion etching) to the semiconductor laminate S of the epitaxial wafer 100. The plasma etching heats the epitaxial wafer 100 to raise the temperature of the wafer during the etching. The resist mask R on the epitaxial wafer 100 is also subjected to the heating, but the epitaxial wafer 100 is cooled through the quartz tray, which is attached to the back face of the wafer 10. This cooling through the quartz tray can prevent the mask from deteriorating during the etching, thereby avoiding excess temperature rise in the etching.

An insufficient adhesion between the tray and the wafer results from voids therebetween to raise the temperature of the wafer, resulting in undesired cooling which may deteriorate the resist mask R and be finally peeled off from the tray during plasma etching.

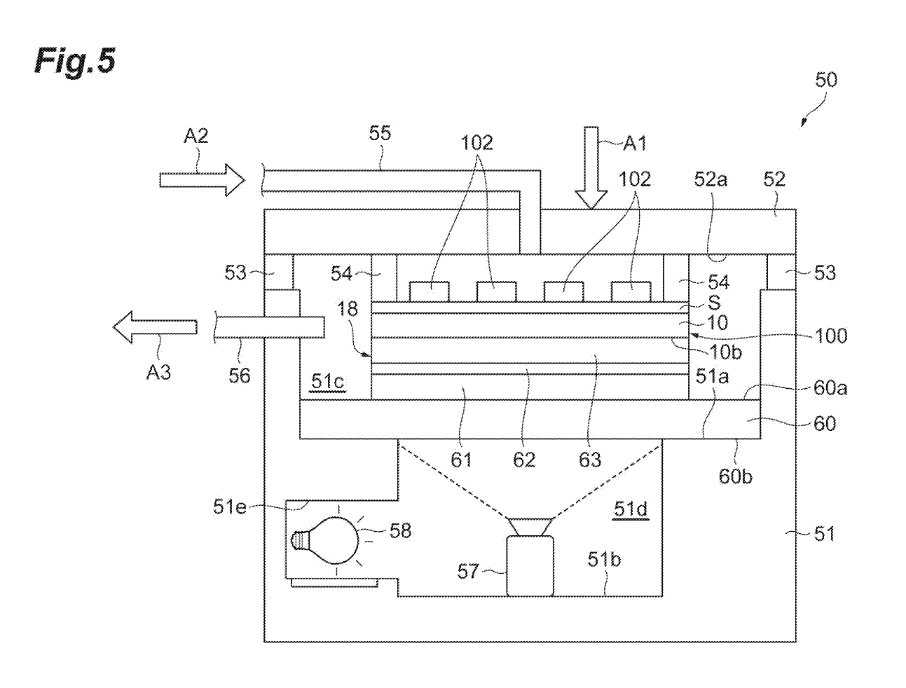

In the present embodiment, sticking the wafer 10 on the tray with an adhesive film, which contains pressure-sensitive material, can bring the wafer 10 into close contact with the tray, thereby providing an intermediate product 18. The intermediate product 18 is loaded into an etching apparatus, which can apply the product to the plasma etching. FIG. 5 is a schematic view showing an apparatus 50 that can form the intermediate product according to the embodiment.

The apparatus 50 includes a container 51, a lid 52, O-rings 53 and 54, a gas-supply pipe 55, an exhaust pipe 56, an imager 57, and an illuminating device 58. The structure body 18 is accommodated in the apparatus 50. The intermediate product 18 includes an epitaxial wafer 100, an adhesive film, and a supporting base, such as a tray 60. The adhesive film includes a film 62, and the film 62 contains pressure-sensitive material. The adhesive film further includes a double-sided adhesive film 61 and a double-sided adhesive film 63.

The tray 60 is transparent to, for example, visible light and has a flat face. The tray 60 is made of, for example, quartz. In the present embodiment, the tray 60 has flat faces 60a and 60b opposite to each other. The wafer 10 has a principal face 10a and a back face 10b, which are opposite to each other. In the present embodiment, the wafer 10 adheres to the tray 60 with an adhesive film including the film 62 containing pressure sensitive material, and if needed, the double-sided adhesive films 61 and 63. The faces 60a and 60b each have an area larger than that of the back face 10b of the wafer 10.

The film 62 includes a sheet-like (thin film) base containing pressure sensitive material, such as PRESCALE (registered trademark) supplied by Fuji Film, and the pressure sensitive material changes its color in accordance with the magnitude of pressure (internal stress) applied thereto. The PRESCALE exhibits white in an initial color and is changed to pink in the presence of a predetermined pressure or more. The film 62 is fixed to the one face 60a of the tray 60 with the double-sided adhesive film 61 therebetween, and the film 62 is fixed to the front face 60b of the tray 60 with the double-sided adhesive film 63 therebetween, thereby forming the adhesive film.

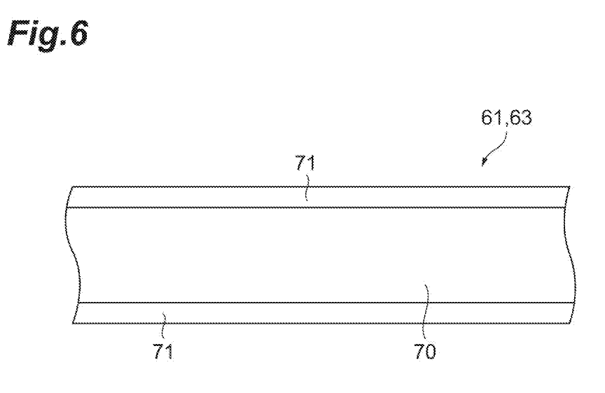

FIG. 6 is a schematic cross-sectional view showing a laminate structure of the double-sided adhesive films 61 and 63. The double-sided adhesive films 61 and 63 each have a sheet-like transparent base material 70 and adhesive layers 71 disposed on respective sides of the base material 70, such as REVALPHA (registered trademark) manufactured by Nitto Denko. The base material 70 is made of resin, such as polyester. One of the adhesive layers 71, for example, the adhesive layer 71 that is in contact with the face of the double-sided adhesive film 63 includes a heat peelable adhesive. The other of the adhesive layers 71, for example the adhesive layer 71 that is in contact with the face of the double-sided adhesive film 61 on the tray 60 also includes a heat peelable adhesive. Alternatively, all of the adhesive layers 71 on the respective faces of the double-sided adhesive films 61 and 63 may include a heat peelable adhesive. Heating the heat peelable adhesive to a predetermined temperature or higher weakens their adhesive force. The double-sided adhesive films 61 and 63, each of which is provided with the base material 70 and the two adhesive layers 71 on respective sides thereof, each have a thickness of, for example, 100 micrometers.

Referring again to FIG. 5, the container 51 has an upper cavity 51c containing the intermediate product 18, and a lower cavity 51d containing the imager 57 and the illuminating device 58, and an upper opening through which the upper cavity 51c communicates with the outside thereof. The upper and lower cavities 51c and 51d are arranged in the vertical direction such that the upper cavity 51c communicates with the lower cavity 51d through a communicating opening, which is formed by an extension stage. The extension stage has a supporting face 51a extending transversely at the boundary between the upper and lower cavities 51c and 51d. The face 51a is oriented upward, and the tray 60 is placed on the face 51a with the tray 60 being supported by the extension stage at the peripheral portion of the other face 60b.

The lid 52 is disposed on the upper opening of the upper cavity 51c of the container 51. The lid 52 has, for example, a plate-like shape and includes a flat face 52a. The lid 52 closes the top opening of the container 51 with the O-ring 53. The O-ring 53 is disposed between the face 52a and the top face of the side wall extending upward from the extension stage that defines the top opening. The O-ring 53 is in contact with both the lid 52 and the container 51 to hermetically seal the upper cavity 51c. The lid 52 can be pressured by an actuator to be moved downward (an arrow A1 in the drawing) and. The magnitude of the pressure ranges from, for example, 0.01 MPa to 0.4 MPa.

The O-ring 54 is disposed between the lower face 52a of the lid 52 and the outer annular area of the top face of the epitaxial wafer 100 (the semiconductor lamination S), and is brought into contact with the lid 52 and the epitaxial wafer 100 to form a pressing space. The pressing space is hermetically sealed with the lid 52, the epitaxial wafer 100, and the O-ring 54 therebetween.

The air-supply pipe 55 penetrates the lid 52 to supply pressing gas to the pressing space, which is defined by the O-ring 54, the lid 52 and the epitaxial wafer 100 (the arrow A2 in the drawing). The gas includes, for example, nitrogen gas. The pressure of the supply gas is, for example, 0.3 MPa. The exhaust pipe 56 penetrates the container 51 outside the O-ring 54, and is used to evacuate the upper cavity 51c outside the pressing space (the arrow A3 in the drawing). The exhaust pressure is, for example, −70 kPa. Using the external force A1, which is applied to the lid 52, and the pressure difference between spaces inside and the outside the O-ring 54 allows the uniform application of the pressing force therefrom to the film between the tray 60 and the principal surface of the epitaxial wafer 100 (the surface on the semiconductor laminate S), thereby uniformly enhancing the adhesion strength between the wafer 100 and the tray 60 over the entire epitaxial wafer 100.

The container 51 is provided with the imager 57, such as a camera, on the bottom 51b of the lower cavity 51d, and the imager 57 can take images of the film 62 through the back face 60b of the tray 60. The difference between images before and after applying the pressing force shows change in color of the film 62. The imager 57 is sensitive to optical wavelengths of indicator range of the film 62. The illuminating device 58 is disposed in the lower cavity 51d to illuminate the lower cavity 51d. The illuminating device 58 emits, for example, visible light. The illuminating device 58 is disposed lateral to the imager 57 in the lateral recess 51e of the lower cavity 51d so as to prevent the illuminating device 58 from directly illuminating the imager 57.

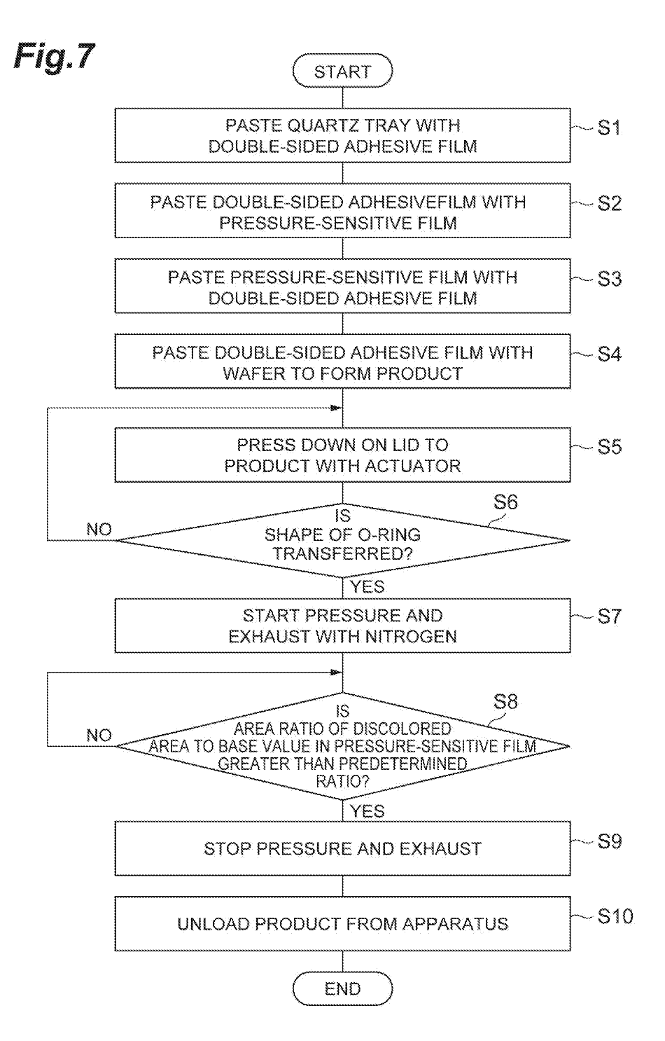

A description will be given of a method of attaching the epitaxial wafer 100 to the tray 60 using the above-described apparatus 50, resulting in that the method forms the intermediate product. FIG. 7 is a flowchart showing a method for producing an intermediate product from a semiconductor laminate product. The present method prepares the double-sided adhesive film 61, the film 62 and the double-sided adhesive film 63. The double-sided adhesive film 61 is pasted on one side 60a of the tray 60 (in step S1), and the film 62 is pasted on the double-sided adhesive film 61 (in step S2). The double-sided adhesive film 63 is pasted onto the film 62 (in step S3) to form a preliminary-stack product including the tray 60 and the films 61 to 63 thereon. The epitaxial wafer 100 is not handled in the above steps S1 to S3 yet, so that a strong pressing force can be applied across the preliminary-stack product, which includes the arrangement of the tray 60 and the films 61 to 63 in contact with each other, to produce a stack product from the preliminary-stack product. The strong pressing force is enough to provide the stack product with a higher thermal conductance, as compared to the preliminary-stack product. The preliminary-stack product may include voids at the interfaces between any adjacent two members among the tray 60 and the films 61 to 63, and the strong pressing force removes a part or all of the voids at the interfaces between any adjacent two members among the tray 60, the double-sided adhesive film 61, the pressure measuring film 62, and the double-sided adhesive film 63 to enhance the adhesive strengths thereat.

After forming the stack product, the epitaxial wafer 100 is placed on the double-sided adhesive film 63 of the stack product (in step S4). The epitaxial wafer 100 is handled in the step S4, and what is needed is to cause the epitaxial wafer 100 to make contact with the double-sided adhesive film 63 of the stack product with no strong pressing force being applied thereto. The epitaxial wafer 100 is placed on the double-sided adhesive film 63 and a light press is applied to the epitaxial wafer 100 with no strong pressing force being applied thereto. The above steps S1 to S4 bring the intermediate product 18 to completion. The intermediate product thus prepared is loaded to the upper cavity 51c of the apparatus 50. Then, the upper cavity 51c is sealed with the lid 52 of the apparatus 50 by use of the actuator (in step S5).

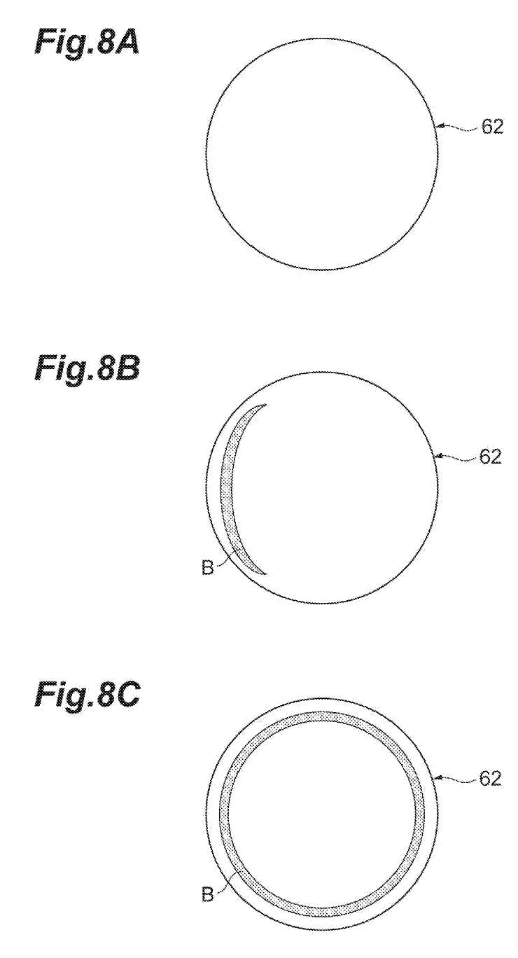

In this step, the actuator applies pressing load to the intermediate product through the lid 52, and the application of the load change the film 62 in color. This change in color can be imaged by the imager 57 through the other side 60b of the tray 60 (in step S6, referred to as the first confirmation step). FIGS. 8A, 8B and 8C are views each showing changes in color of the film 62 in step S5 by hatching, labeled as “B”, (hereinafter referred to as a discolored region) each represent change in color in the film 62 in accordance with the load. Referring to FIG. 8A, the epitaxial wafer 100 receives no pressure through the lid 52, so that the film 62 has an initial color. Gradual increase in the load through the lid 52 also applies the pressing force to the top face of the epitaxial wafer 100 through the O-ring 54. Increase in the pressing force changes color in a part of the film 62, which is under the O-ring 54, as shown in FIG. 8B.

A further increase in the pressing force patterns the film 62 in change in color into an annular closed shape, which is associated with the shape of the O-ring 54, as shown in FIG. 8C, thereby transferring the shape of the O-ring 54 to the film 62 to form the discoloration area B. In order to identify differences in change in color among various patterns of the film 62, the imager 57 takes multiple images of the patterned film 62. Forming the discoloration area B in the film 62 can bring the epitaxial wafer 100 into close contact with the stack product. The application of the pressing force to the epitaxial wafer 100, which may be warped, through the O-ring 54 makes the warpage of the epitaxial wafer 100 reduced. Uniformly-patterning the film 62 makes the contact pressure between the O-ring 54 and the epitaxial wafer 100 uniform. The load, which is applied the lid 52, is increased until images containing discoloration areas B from the imager show that the shape of the O-ring 54 has been transferred to the film 62, and the pressing with the lid 52 is stopped. These steps result in that the lid 52 closes the opening of the cavity 51c to hermetically seal the inner section, which the epitaxial wafer 100 and the O-ring 53 define. The above steps bring the intermediate product to the completion.

After forming the intermediate product, an additional pressing force is applied to the inner section between the tray 60 and the face of the epitaxial wafer 100 (in step S7). Specifically, the supply of gas is started, so that the gas is introduced to the inner section, formed by the O-ring 53, the lid 52 and the epitaxial wafer 100, through the air-supply pipe 55, and the exhaust of the upper cavity 51c is started, so that the upper cavity 51c is exhausted through the exhaust pipe 56. An exemplary process is as follows: the exhaust for 1 minute; and thereafter, both the evacuation and the supply for 1 minute (to provide pressurization).

the application of the air pressure through the inner section to the epitaxial wafer 100 causes change in color of the film 62. The imager 57 takes images through the other side face 60b of the tray 60 during the pressing process. The images show that a sufficiently high pressure can bring the epitaxial wafer into close contact with the stack product entirely. Specifically, two images from the imager before and after the pressurization have respective discolored areas B in the film 62, the color of which has changed, in the inner section that is defined by the O-ring 54. The difference in the ratio of the area of the discolored region B to the total area of the inner section between the two images show that the desired contact between the stack product and the epitaxial product has been achieved over the principal surface of the epitaxial product (for example, 80% or 90% or more), e.g., the total area of the inner section (in step S8, hereinafter referred to as the second checking step).

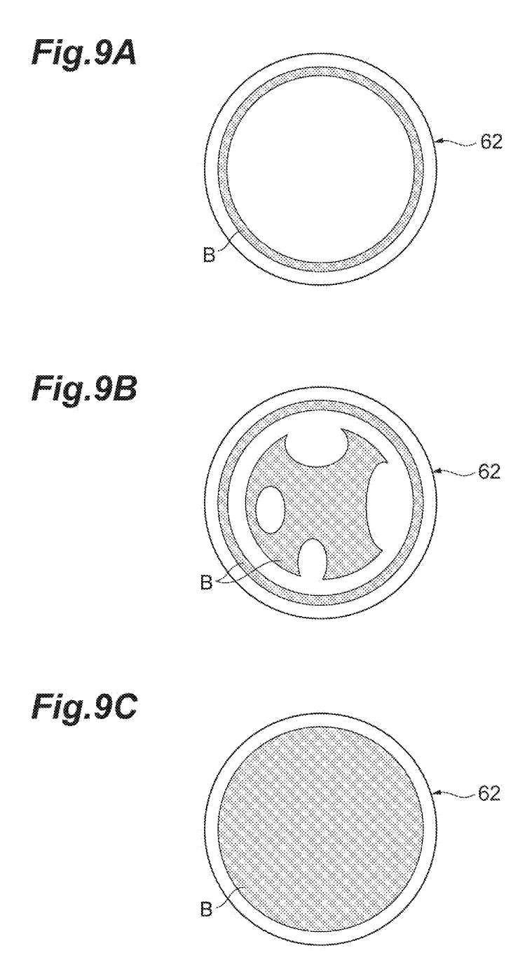

FIGS. 9A, 9B and 9C are views showing changes in color of the film 62 in images taken by the imager 57 in step S8. As shown in FIG. 9A, no pressure difference is produced by the supply and exhaust, which is conducted through the air-supply pipe 55 and the exhaust pipe 56, so that the pressure in the inner section does not apply no additional pressure to the epitaxial wafer 100, so that there is no change in color over the film 62. As shown in FIG. 9B, the supply and exhaust with the air-supply pipe 55 and the exhaust pipe 56 can apply, to the surface of the epitaxial wafer 100, the pressure difference between the inner and outer sections, which are defined with respect to the O-ring 54, to form sparsely-colored areas inside the transfer area of the film 62.

The above supply and exhaust process forms a sufficiently large pressure difference between the inside and outside of the O-ring 54, which creates a uniform pressing force that entirely presses the inside area of the epitaxial wafer 100 against the tray 60, as shown in FIG. 9C. This uniform pressing force allows the film 62 to uniformly change in color inside the closed area, which is patterned in the shape of the O-ring 54. Images from the imager 57 can show that the pressing force has been applied between the face of the epitaxial wafer 100 and the tray 60 to fully change the film 62 in color. The analysis of the images calculates the area ratio of the discoloration region B to the area inside the O-ring 54, and if the area ratio is less that a predetermined ratio, both the load onto the lid 52 and the supply pressure of gas through the air-supply pipe 55 can be raised to enhance the area ratio in change in color. The load and the supply pressure of gas are raised until the area ratio exceeds the predetermined ratio. In response to the area ratio exceeding the predetermined ratio, the supply/exhaust through the pipes 55 and 56 is stopped (in step S9).

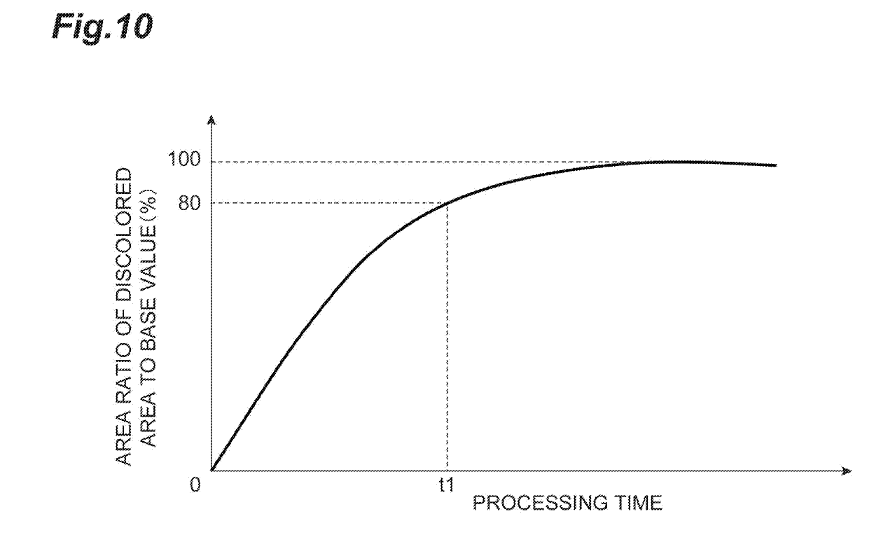

FIG. 10 is a graph showing a curve indicating change in the area ratio of the discoloration region B to the area inside the O-ring 54 in step S8, where the horizontal axis represents the air-supply/discharge time and the vertical axis represents the area ratio. As shown in FIG. 10, after starting the supply/exhaust through the pipes 55 and 56, the area ratio rises monotonically with the lapse of time. The area ratio gradually approaches 100%, and in the present embodiment, the area ratio reaches the predetermined value at time t1 to stop the supply/exhaust.

As such, the above steps can produce the intermediate product 18, which is unloaded out from the apparatus 50 (in step S10), with the area ratio of not less than the predetermined value. The above steps S1 to S10 bring the intermediate product 18 to completion.

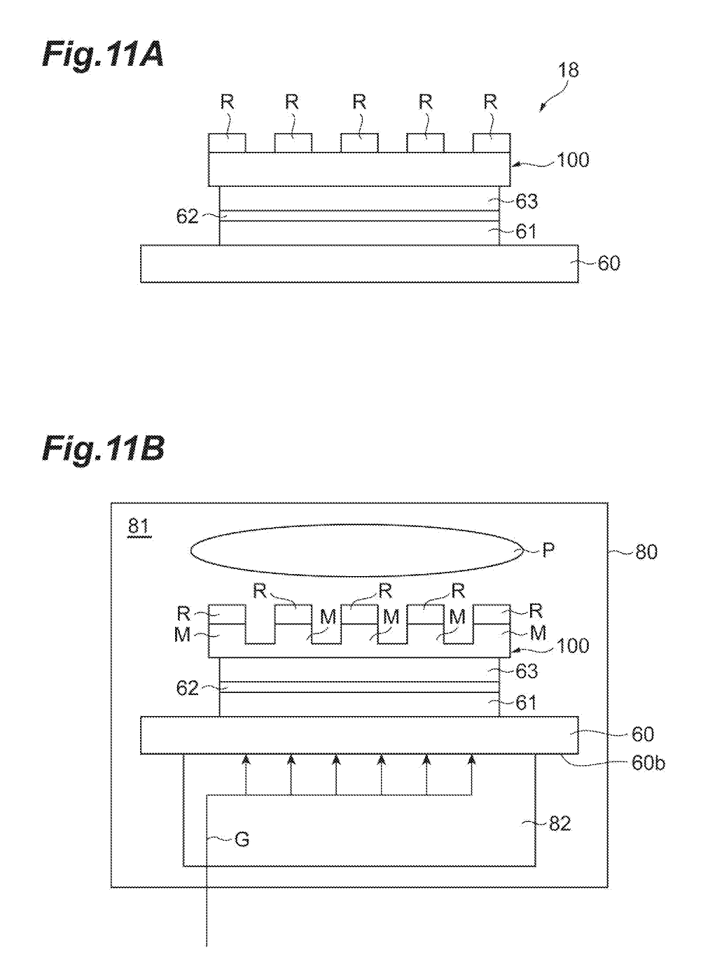

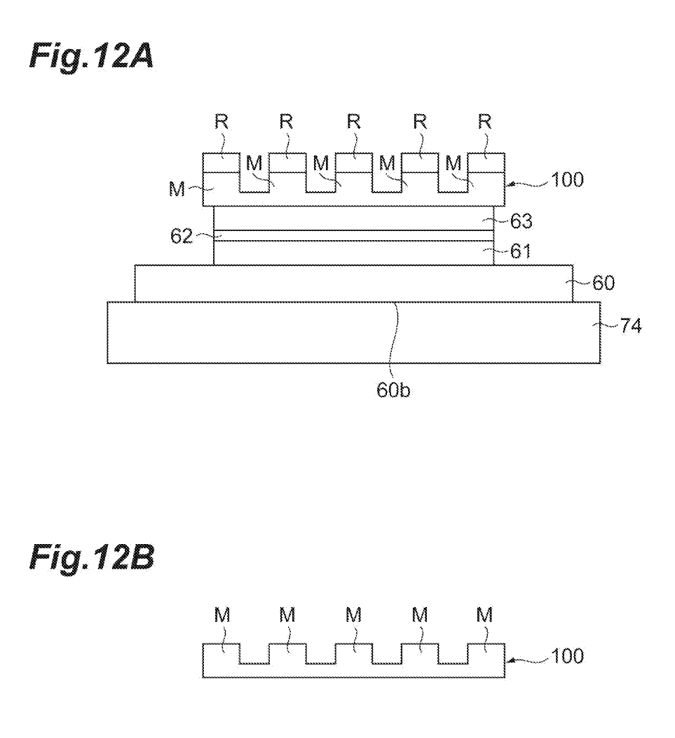

The intermediate product 18 is loaded to an etching apparatus enabling plasma etching, and the semiconductor laminate S of the epitaxial wafer 100 in the intermediate product 18 is etched with the resist mask (in etching step). FIGS. 11A, 11B, 12A and 12B are schematic views each showing a major step in the etching process.

As shown in FIG. 11A, the intermediate product 18 is prepared, for example, by the above-described steps. As shown in FIG. 11B, the epitaxial wafer 100 is loaded to the vacuum chamber 81 of a plasma etching apparatus 80. The plasma etching apparatus 80 enables, for example, reactive ion etching (RIE), and the plasma etching is carried out by, for example, an inductively coupled plasma reactive ion etching (abbreviated by ICP-RIE) apparatus. The ICP power ranges from, for example 50 to watts, and the bias power ranges from, for example, 50 to 500 watts. The plasma etching apparatus 80 includes an electrostatic chuck 82, and the tray 60 is supported by the electrostatic chuck 82 on the face 60b. The electrostatic chuck 82 is provided with a pipe for cooling, and the pipe supplies, to the back face 60b of the tray 60, a cooling gas G, such as He gas, cooled by a chiller. Cooling the tray 60, blown by the coolant, removes heat from the epitaxial wafer 100, thereby cooling the epitaxial wafer 100. The epitaxial wafer 100 is subjected to the plasma P, but cooling the epitaxial wafer 100 through the tray 60 can reduce the temperature rise in the epitaxial wafer 100, so that the temperature of the epitaxial wafer 100 can be kept, for example, 100 degrees Celsius or lower. The temperature of the cooling gas G ranges, for example, from 10 to 20 degrees Celsius.

After the cooling, the etching apparatus starts to supply an etching gas to the vacuum chamber 81 while cooling the tray. The etching gas may contain chlorine-based gas, for example, BCl₃ gas or a mixture of BCl₃ and Cl₂, and further contains inert gas (for example, Ar gas), which are supplied to the vacuum chamber 81. The gas is supplied to the vacuum chamber 81 by a total flow rate of, for example, 100 sccm. Specifically, in the chlorine-based gas of BCl₃, the etching gas contains BCl₃, which is supplied in the flow rate of 30 sccm; and Ar, which is supplied in the flow rate of of 70 sccm. In a mixture of the chlorine-based gas, the etching gas contains BCl₃, which is supplied in the flow rate of 20 sccm; Cl₂, which is supplied in the flow rate of 10 sccm; and Ar, which is supplied in the flow rate of 70 sccm. Plasma-ignition starts to turn the etching gas into plasma in the vacuum chamber 81, and ion species in the plasma P collide with the upper face of the epitaxial wafer 100 (the semiconductor laminate S). Both sputtering by ions and chemical reaction with the etching gas occur in the vacuum chamber 81 to etch the surface of the epitaxial wafer 100 with the resist mask.

After the etching, the intermediate product thus etched is loaded out from the vacuum chamber 81. Then, the epitaxial wafer 100 thus etched is separated from the film 62 (in the separation step). In the intermediate product that provides, with heat peelable adhesive, the adhesive layers 71 (as shown in see FIG. 6) of the double-sided adhesive film 63 on the etched epitaxial wafer 100. As shown in FIG. 12A, the hot plate 74 makes contact with the face 60b of the tray 60 to heat the etched intermediate product 18 with the hot plate 74. Heating thermally-foams the heat peelable adhesive material to reduce the adhesive force (adhesion), thereby peeling off the double-sided adhesive film 63 from the etched epitaxial wafer 100. The double-sided adhesive film 63 on the film 62 is provided with one of the adhesive layers 71, and the adhesive layers 71 on both sides of the double-sided adhesive film 61 can be provided with heat peelable adhesive material, and the heating can thermally-foam the heat peelable adhesive material to reduce the adhesive force (adhesion strength), thereby peeling off the double-sided adhesive film 61. The above process can reliably separate the epitaxial wafer 100 from the tray 60. As shown in FIG. 12B, the resist mask R is removed from the etched epitaxial wafer 100. The temperature of the hot plate 74 is, for example, 150 degrees Celsius.

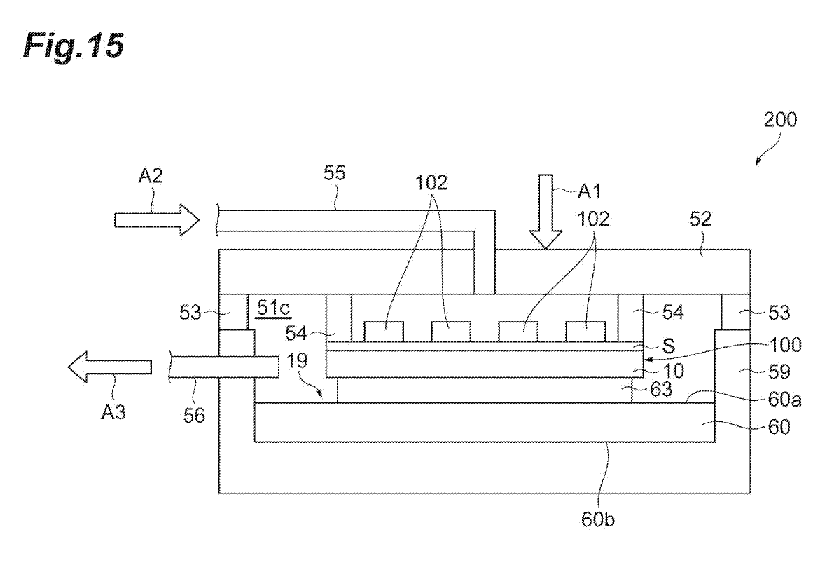

A description will be given of advantageous effects of the method for fabricating the optical device according to the above-described embodiment. FIG. 15 is a schematic view showing another apparatus. As shown in FIG. 15, the apparatus 200 includes a container 59, a lid 52, O-rings 53 and 54, an air-supply pipe 55, and an exhaust pipe 56. The container 59 includes a single cavity, which is different from the container 51 having the lower space 51d (shown in FIG. 5) of the above embodiment. Further, a stack product is prepared which is provided with the double-sided adhesive film 63 and the tray 60, and excludes the film 62. Further, an intermediate product 19 is prepared which is provided with the epitaxial wafer 100 and the above stack product of the tray 60 and the double-sided adhesive film 63, which bonds the back face 10b of the epitaxial wafer 100 to the tray 60. The intermediate product 19 thus prepared is loaded to an apparatus 50. The apparatus 200, which operates in a manner similar to the apparatus 50 according to the present embodiment, supplies air to the single cavity through the air-supply pipe 55 and exhausts the single cavity through the exhaust pipe 56 to produce a pressure difference between the inside and outside of the O-ring 54, thereby applying a pressing force from the pressure difference to the tray 60 and the face of the epitaxial wafer 100. The pressing force is exerted on the epitaxial wafer 100, which adhere to the tray 60 with the double-sided adhesive film 63.

The epitaxial wafer 100 may not sufficiently adhere to the tray 60 because of voids left at interfaces between the double-sided adhesive film 63 and the tray 60 and epitaxial wafer 100. The voids at the interfaces are evacuated during the plasma etching to make the thermal conductance between the epitaxial wafer 100 and the tray 60 reduced, thereby leading to insufficient cooling of the epitaxial wafer 100 through the tray 60. The reduced thermal conductance raises the temperature of the epitaxial wafer 100 during the plasma etching. An excessive temperature rise may deteriorate the resist mask R on the epitaxial wafer 100 to make the resist mask R defective. A defective resist mask makes the etching undesired, so that the epitaxial wafer 100 is subjected to the etching with the defective resist mask to produce a defective etched product from the epitaxial wafer 100, resulting in reduced yield.

The intermediate product according to the embodiment is provided with the film 62 between the tray 60 and the epitaxial wafer 100 to avoid the reduction in the thermal conductance between the epitaxial wafer 100 and the tray 60. The film 62 changes its color in response to the pressing force. Specifically, the change in color may vary over the surface of the epitaxial wafer 100, and can be observed through the back face 60b of the tray 60. The observation of the change in color in the film 62 in view of uniformity shows whether the application of a pressing force to between the epitaxial wafer 100 and the tray 60 cannot bring the tray 60 and the epitaxial wafer 100 into close contact with each other. If needed, the pressing and the observation are conducted repeatedly to obtain an intermediate product with an acceptable variation in color over the surface of the epitaxial wafer 100. Containing the film 62 in the stack product can visualize the distribution of the insufficient adhesion between the tray 60 and the epitaxial wafer 100 over the face of the epitaxial wafer 100. The fabricating method according to the present embodiment can prevent the resist mask in the intermediate product from becoming defective during plasma etching, thereby avoiding the reduction in yield.

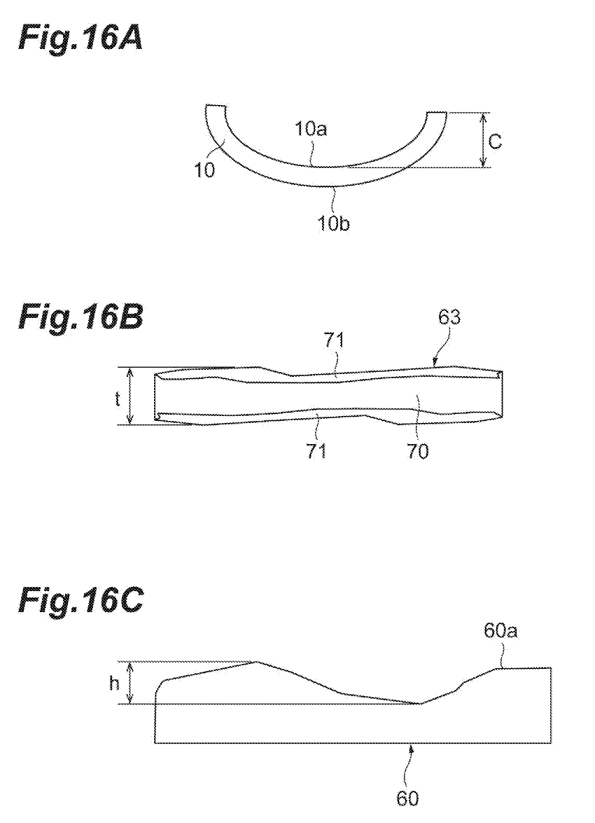

FIGS. 16A, 16B and 16C are schematic views each showing an exemplary the epitaxial wafer 100. Referring to FIG. 16A, a wafer 10 has a warpage C, which may vary for each wafer, for example, of 5 to 50 micrometers. The warpage C makes it difficult for the outer peripheral of the wafer 10 to adhere to the tray 60, thereby leaving voids at the interfaces in the intermediate product. The fabricating method according to the present embodiment includes applying the pressing force to the wafer through the O-ring 54 to pattern the film 62 in a contact shape of the O-ring 54, thereby forming the discolored area B (shown in FIG. 8C), and verifying that the film 62 has been patterned in response to the pressing through the O-ring 54 that is in contact with the wafer. Transferring the contacting shape of the O-ring 54 to the film 62 by pressing the wafer with the O-ring 54 and the lid 52 can flatten the wafer to make the warpage C less, which can bring the wafer with warpage C into close contact with the tray.

FIG. 16B is an enlarged cross sectional view showing the double-sided adhesive film 63. The double-sided adhesive film 63 includes a basal material 70 and adhesive layers 71 on the both sides thereof. The basal material 70 has roughness on each face thereof. The surface roughness causes the adhesive layers 71 to vary in thickness over the surface of the basal material 70, thereby making the thicknesses of the adhesive layers 71 non-uniform. The double-sided adhesive film 63 has variations in thickness “t”, and specifically, has a design value of, for example, 100 micrometers and a tolerance of about ±5 micrometers in thickness “t”. The variations in thickness “t” may form voids at the interfaces between the tray 60 and epitaxial wafer 100 and the stack produce that includes the double-sided adhesive film 63. FIG. 16C is an enlarged cross-sectional view showing the face of the tray 60. The tray 60 is made of, for example, quartz. The flat face 60a of the tray 60 is formed by grinding, which form an undulation on the face ground. The face 60a has an undulation, which has a maximal difference in height “h” between the peaks and valleys of, for example, 50 micrometers. The tray 60 with a wavy surface may form voids at the interfaces between the tray 60 and epitaxial wafer 100 and the stack produce that includes the double-sided adhesive film 63. The fabricating method according to the present embodiment includes applying the air pressure to the wafer and verifying that the film 62 has been changed in color in almost all area inside the O-ring 54 (shown in FIG. 9C). The remaining voids in the intermediate product can be removed by an additional supply pressure of the gas from the air-supply pipe 55.

The fabricating method according to the embodiment can detect a foreign particle between the epitaxial wafer 100 and the tray 60. The foreign material, left between the epitaxial wafer 100 and the tray 60, may break the epitaxial wafer 100 during the depressurization with the apparatus 50, and can be found, based on a difference in the shape of the discolored region B, by the observation of the intermediate product before the pressing. The foreign material thus found is removed by separating the epitaxial wafer 100 from the tray 60. After excluding a foreign material, a new intermediate product is produced from the epitaxial wafer 100 and the tray 60, thereby reducing the occurrence of cracking of the epitaxial wafer 100.

In the embodiment, the film 62 can be provided with the ratio of the area of the region B to the inside area within the O-ring 54 is not less than 80% or 90%, and after this ratio in color change has been given to the film 62, the present method can determine whether or not an intermediate product is provided with a uniform adhesion between the tray 60 and the epitaxial wafer 100 over the inside area of the entire surface of the epitaxial wafer 100. Analyzing images from the imager 57 on a controller, such as a computer, allows the automatic determination.

In the embodiment, the intermediate product 18 may be provided with the stack product, which includes the film 62 and the double-sided adhesive films 61 and 63, having a heat peelable adhesive making close contact with the epitaxial wafer 100. The intermediate product 18 may be provided with the stack product, which includes the film 62 and the double-sided adhesive films 61 and 63, having both a heat peelable adhesive making close contact with the epitaxial wafer 100 and a heat peelable adhesive making close contact with the film 62. One or more heat peelable adhesives make it easy to separate the film 62 and the epitaxial wafer 100 from each other after the plasma etching.

In the present embodiment, the intermediate product 18 may be provided with the stack product, which includes the film 62 and the double-sided adhesive films 61 and 63, having a heat peelable adhesive making close contact with the tray 60. The intermediate product 18 may be provided with the stack product, which includes the film 62 and the double-sided adhesive films 61 and 63, having both a heat peelable adhesive making close contact with the tray 60 and a heat peelable adhesive making close contact with the film 62. One or more heat peelable adhesives make it easy to separate the film 62 and the tray 60 from each other after the plasma etching.

The present embodiment can fabricate the semiconductor optical device, such as VCSEL. The fabrication of VCSEL excludes processes for wet-etching with hydrofluoric acid and dry-etching with a fluorocarbon gas, so that silicon-based inorganic material, such as silicon oxide and silicon nitride cannot be used for an etching mask, whereby the fabrication of VCSEL needs a resist mask for etching. The fabricating method that cools the resist mask through the epitaxial wafer according to the embodiment is particularly effective.

(Modification)

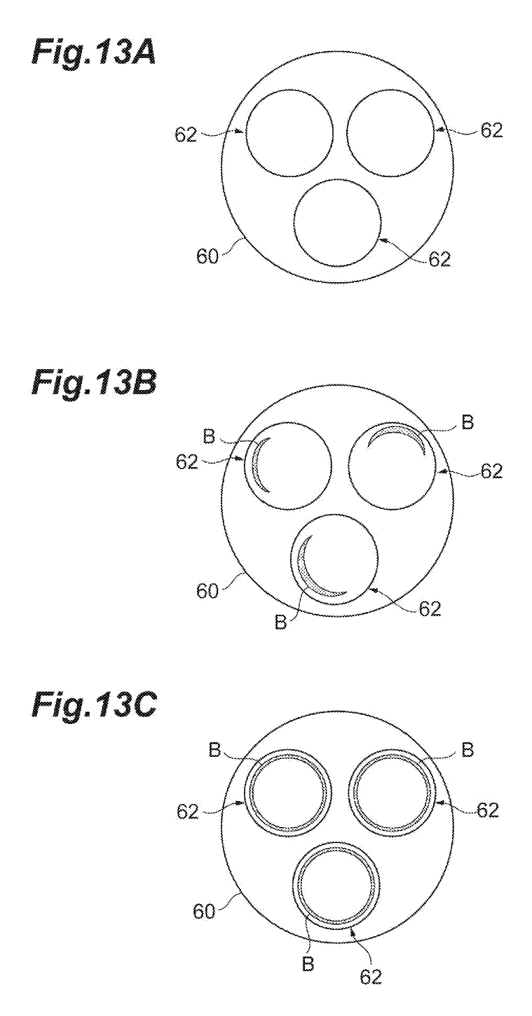

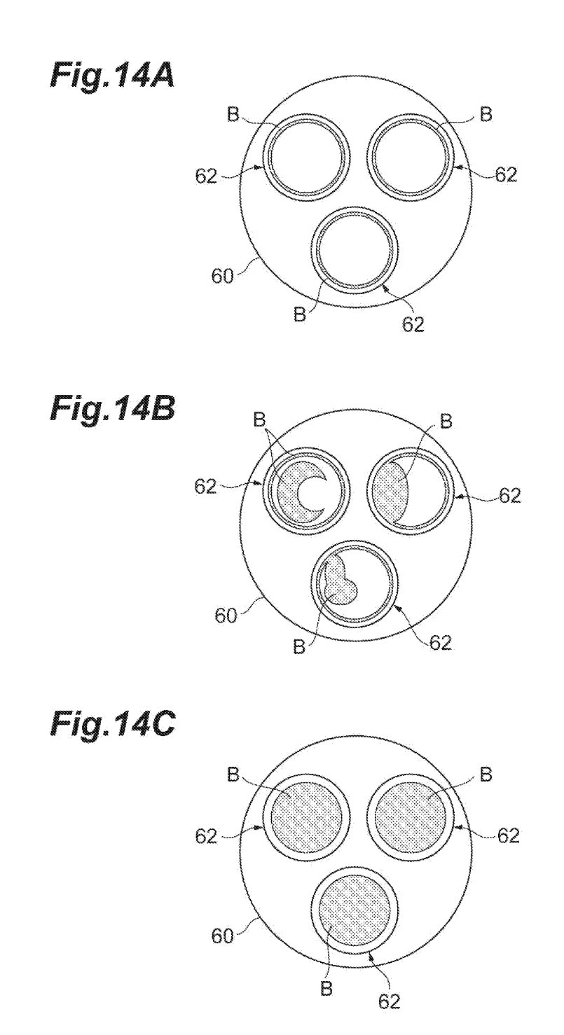

A description will be given of a modified example according to the embodiment below. FIGS. 13A, 13B, 13C, 14A, 14B and 14C are schematic top views each showing the back side of the intermediate product illustrating a shape of the discoloration region B of the film 62 in the bonding step, and are associated with those of FIGS. 8A to 9C. An intermediate product according to the modified example includes multiple epitaxial wafers 100 (specifically, three epitaxial wafers 100) and a single tray 60. The three epitaxial wafers 100 are disposed on the face 60a of the tray 60 and are bonded to the single tray 60 with one or more epitaxial wafers 100. Three O-rings 54 are prepared for each epitaxial wafer 100. The modified example also has advantageous effects that is similar to those of the above embodiment.

The method of fabricating a semiconductor optical device according to the present invention is not limited to the above-described embodiments, and various other modifications are possible. For example, the method for fabricating a VCSEL can be applied to the methods for fabricating a light receiving or emitting device. Further, the above embodiment uses a heat peelable adhesive but may use various other adhesive materials.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. A method for fabricating a semiconductor optical device comprising:
preparing a product having a supporting base with a top face and a back face, a semiconductor product mounted on the top face, and an adhesive film including a film containing pressure sensitive material, the adhesive film being between the semiconductor product and the supporting base in the product, and the semiconductor product including a semiconductor laminate and a patterned resist layer on the semiconductor laminate;
applying force to the product to produce an intermediate product from the product, the adhesive film bonding the semiconductor product and the top face of the supporting base to each other;
disposing the intermediate product on a stage of an etching apparatus; and
etching the semiconductor product in the intermediate product with the patterned resist layer in the etching apparatus while the semiconductor product being cooled through the stage.

2. The method according to claim 1, wherein the stage of the etching apparatus is coupled to a cooler, and the stage is in contact with the back face of the supporting base.

3. The method according to claim 1, wherein etching apparatus processes the semiconductor product by plasma-etching.

4. The method according to claim 1, wherein the adhesive film has a heat-peelable adhesive sheet between the semiconductor product and the top face of the supporting base.

5. The method according to claim 1, wherein the adhesive film has a heat-peelable adhesive sheet between the supporting base and the semiconductor product.

6. The method according to claim 1, wherein the adhesive film has a first heat-peelable adhesive sheet between the adhesive film and the top face of the supporting base, and a second heat-peelable adhesive sheet between the adhesive film and the semiconductor product.

7. The method according to claim 1, wherein the semiconductor product includes semiconductor layers for an upper distributed Bragg reflector, an active layer and a lower distributed Bragg reflector.

8. The method according to claim 1, wherein the semiconductor optical device includes a vertical cavity surface emitting laser, and the patterned resist layer defines a mesa shape for the vertical cavity surface emitting laser.

9. The method according to claim 1, wherein the supporting base is made of quartz glass.

10. The method according to claim 9, wherein applying force to the product includes disposing an O-ring on the patterned resist layer, disposing a lid on the O-ring and the patterned resist layer to form a hermetically sealed cavity, and depressurizing the hermetically sealed cavity to apply the force to the intermediate product while illuminating the back face with rays of light.
